(19) United States
(12) Patent Application Publication
(10) Pub. No.: US 2024/0356484 A1
(43) Pub. Date: Oct. 24, 2024

(54) ELECTRICAL SOLAR DEVICE AND SYSTEM FOR ARCHITECTURAL USES

(71) Applicant: SOLAR FENCE GROUP LTD, Kfar Chabad (IL)

(72) Inventor: Menashe ALTHOUS, Kfar Chabad (IL)

(73) Assignee: SOLAR FENCE GROUP LTD, Kfar Chabad (IL)

(21) Appl. No.: 18/577,711

(22) PCT Filed: Aug. 4, 2022
(86) PCT No.: PCT/IL2022/050853

§ 371 Date: Jan. 9, 2024

Related U.S. Application Data
(60) Provisional application No. 63/229,808, filed on Aug. 5, 2021.
(60) Provisional application No. 63/229,818, filed on Aug. 5, 2021.
(60) Provisional application No. 63/317,105, filed on Mar. 7, 2022.

(51) Int. Cl. H02S 20/24; H02S 30/10; H02S 40/40

(52) U.S. Cl. CPC H02S 20/24; H02S 30/10; H02S 40/40

(57) ABSTRACT

A prefabricated solar construction element is disclosed that comprises a building construction element ready to be integrated into an architectural building, a plurality of solar cells carriers, and a plurality of solar cells attached to the plurality of solar cells carriers, wherein the solar cells generate electric power in response to light. The prefabricated solar construction element is prefabricated by integrating the construction element, the plurality of solar cells carriers, and the plurality of solar cells, prior to integrating the prefabricated solar construction element into the architectural building.

### TECHNICAL FIELD

The present subject matter relates to solar energy. More specifically, the present subject matter relates to using 3D multi-facets solar units for electrical energy generation in fences, buildings, walls, roofs and the likes, and to modular structural units incorporating solar cells.

### BACKGROUND

Solar energy plays an important role in variety of applications in many energy-related fields: energy for remote locations, agriculture, utility grid support, telecommunication, industrial processes, and other green environmental energy resources.

Photovoltaic (PV) cells are the leading technology to convert solar energy into electricity. Photovoltaic power systems are in wide use; however, their main drawbacks are high price and low efficiency.

Concentrators for solar cells can be used for increasing efficiency of collection but have not yet mature due the high cost involved in building efficient collectors and sun trackers.

Solar photovoltaic panels of the prior art are usually deployed as flat constructions on rooftops or other substantial horizontal surfaces that faces the radiation coming from the sun direction. Those structures are not adequate for any roof since there are roofs such as greenhouse roofs that cannot be blocked from the natural sun by the flat structures. Moreover, those structures cannot be used on structures that are vertical to the direction of the sun light. The constructions are relatively heavy structures that are relatively expensive since they have to endure massive winds and are prone to dust and dirt that tend to accumulate on the flat structures. Moreover, not every roof can endure the heavy weight constructions that hold the solar panels.

### BRIEF SUMMARY

According to a first aspect of the present disclosed subject matter, a prefabricated solar construction element is provided, the prefabricated solar construction element comprises: a building construction element ready to be integrated into an architectural building; a plurality of solar cells carriers; and a plurality of solar cells attached to the plurality of solar cells carriers, wherein the solar cells generate electric power in response to light, wherein the prefabricated solar construction element is prefabricated by integrating the construction element, the plurality of solar cells carriers, and the plurality of solar cells, prior to integrating the prefabricated solar construction element into the architectural building.

The prefabricated solar construction element of Claim 1, wherein the architectural building is a modular industrial building.

In some exemplary embodiments, the modular industrial building is a warehouse.

In some exemplary embodiments, the modular industrial building is a residential house.

In some exemplary embodiments, the building construction element comprises: an inner plate; an outer plate; and a thermal isolation layer sandwiched in between the inner plate and the outer plate, and wherein the plurality of solar cells carriers are attached to the outer plate.

In some exemplary embodiments, the building construction element comprises: an inner plate; an outer plate; and a thermal isolation layer sandwiched in between the inner plate and the outer plate, and wherein the plurality of solar cells carriers is a part of the outer plate.

The prefabricated solar construction element of claim 1, wherein the building construction element comprises a transparent plate.

In some exemplary embodiments, the building construction element is a transparent plate allowing a portion of the light to pass through the prefabricated solar construction element.

In some exemplary embodiments, at least a portion of the transparent plate is in a zig-zag shape, such that all the zig section are at a first angle relative to the plate, and all the zag section are at a second angle relative to the plate, and wherein the zig sections are the plurality of solar cells carriers.

In some exemplary embodiments, the transparent plate is double-glazed to provide thermal insulation.

In some exemplary embodiments, the transparent plate is tinted.

In some exemplary embodiments, the prefabricated solar construction element is uses as a window.

In some exemplary embodiments, the prefabricated solar construction element is uses as a part of a roof.

In some exemplary embodiments, the roof is a roof of a green house.

In some exemplary embodiments, the solar cells carriers are made of metal.

In some exemplary embodiments, the plurality of solar cells carriers are tilted at a tilting angle respective to the prefabricated solar construction element.

In some exemplary embodiments, the tilting angle is selected according to the latitude where the architectural building is to be located.

In some exemplary embodiments, the tilting angle is selected according to one of: in north Europe where the sun only reaches 55 to 60 degrees over the horizon in mid-day, the tilting angle is between 50 to 60 degrees; in central Europe where the sun only reaches 65 to 70 degrees over the horizon in mid-day, the tilting angle is between 35 to 45; in Israel where the sun reaches 80 degrees over the horizon in mid-day, the tilting angle is between 20 to 30; in China, where the sun reaches 95 degrees over the horizon in mid-day, the tilting angle is between 20 to 30; and in New York, where the sun reaches 72 degrees over the horizon in mid-day, the tilting angle is between 35 to 45.

In some exemplary embodiments, the prefabricated solar construction element is uses as a part of a wall.

In some exemplary embodiments, the prefabricated solar construction element is uses as a part of a roof.

In some exemplary embodiments, the prefabricated solar construction element is uses as a part of a fence.

In some exemplary embodiments, the fence is an acoustic fence.

In some exemplary embodiments, the three-dimensional structure of the face of the acoustic fence has better sound absorbing properties than a flat surface acoustic fence.

In some exemplary embodiments, the weight of the prefabricated solar construction element is less than 50% of the weight of a solar construction of comparable size.

According to another aspect of the present disclosed subject matter, a dual sided solar unit is provided, the dual sided solar unit comprises: at least a first transparent plate, the first transparent plate is three dimensionally structured, having a first face comprising a plurality of facets oriented in a plurality of angles in respect to the first transparent plate; and a plurality of solar cells attached to at least some of the plurality of facets, and wherein the solar cells generate electrical power in response to light falling on any side of the dual sided solar unit.

In some exemplary embodiments, the plurality of solar cells are thin-film solar cells.

In some exemplary embodiments, the plurality of solar cells are dual-sided solar cells, intended to generate electricity in response to light received on any sided of the dual-sided solar cells.

In some exemplary embodiments, the plurality of solar cells are single-sided solar cells, intended to generate electricity in response to light received on the active face of the single-sided solar cells, wherein the active faces of the single-sided solar cells are facing the sun-facing side of the first transparent plate, and wherein at least a portion of the light arriving to the side opposing the sun-facing side of the first transparent plate is reflected or refracted to fall on the active faces of the single-sided solar cells.

In some exemplary embodiments, the dual sided solar unit further comprises a second transparent plate three dimensionally structured and having a first face comprising a plurality of facets, wherein the facets are oriented in a plurality of angles in respect to the second transparent plate, wherein the three-dimensional structure of the first face of the second plate match the three-dimensional structure of the first face of the second plate, and wherein the first transparent plate and the second transparent plate are attached together so that the plurality of solar cells are sandwiched in between the two transparent plates.

In some exemplary embodiments, the dual sided solar unit operates to generate solar power when positioned vertically.

In some exemplary embodiments, at least one of the first transparent plate or the second transparent plate is a thick, blast resisting plate.

In some exemplary embodiments, the blast resisting plate is made of polycarbonate material.

An aspect of the present disclosed subject matter relates to modular solar panel constructions. More particularly, the present disclosed subject matter relates to 3-dimensional bases to be used as solar panel constructions.

In some embodiments, light constructions that can be positioned as vertical structures acting as basis for the photovoltaic cells are needed in order to overcome those shortcomings.

Another aspect of the present disclosed subject matter is to provide a three-dimensional structure having a first surface and an opposite surface for use as a basis for solar cells. The solar cells are adhered on one or both the surfaces. The solar panels are incorporated within the structure so there is no need for a dedicated additional support onto which the construction of the solar panels is positioned.

Another aspect of the present disclosed subject matter is to provide a solar construction comprising a three-dimensional sheet having a first surface and an opposite surface; and solar cells adhered on at least a portion of at least one of the first surface and the opposite surface.

Yet another aspect of the present disclosed subject matter is to provide a solar three-dimensional construction that can be used as roofs, partially transparent roofs, covering of walls, fences, portion of buildings, a combination thereof or the like.

Unless otherwise defined, all technical and scientific terms used herein have the same meaning as commonly understood by one of ordinary skill in the art to which this disclosed subject matter belongs. Although methods and materials similar or equivalent to those described herein can be used in the practice or testing of the present disclosed subject matter, suitable methods and materials are described below. In case of conflict, the specification, including definitions, will control. In addition, the materials, methods, and examples are illustrative only and not intended to be limiting.

The features as indicated above can be combined individually or all together.

### BRIEF DESCRIPTION OF THE DRAWINGS

Some embodiments of the disclosed subject matter described, by way of example only, with reference to the accompanying drawings. With specific reference now to the drawings in detail, it is stressed that the particulars shown are by way of example and for purposes of illustrative discussion of the preferred embodiments of the present disclosed subject matter only, and are presented in the cause of providing what is believed to be the most useful and readily understood description of the principles and conceptual aspects of the disclosed subject matter. In this regard, no attempt is made to show structural details of the disclosed subject matter in more detail than is necessary for a fundamental understanding of the disclosed subject matter, the description taken with the drawings making apparent to those skilled in the art how the several forms of the disclosed subject matter may be embodied in practice.

In the drawings:

FIG. 1A, schematically depicts a house with solar panel constructions installed on its roof relative to the sun trajectory, according to the prior art.

FIG. 1B, schematically depicts a solar panel array constructions installed a horizontal surface, relative to the sun trajectory, according to the prior art.

FIG. 2A, schematically depicts an acoustic barrier, according to the prior art.

FIG. 2B, schematically depicts a security barrier, according to the prior art.

FIG. 3A schematically illustrates different types of surfaces to be provided with solar cells, in accordance with embodiments of the disclosed subject matter.

FIG. 3B(i) schematically illustrates a cross sectional view of a solar fence, in accordance with embodiments of the disclosed subject matter.

FIG. 3B(ii) schematically illustrates a cross sectional view of a solar fence having improved ballistic protection, in accordance with embodiments of the disclosed subject matter.

FIG. 3C schematically illustrates a 3-dimensional solar structure, in accordance with some exemplary embodiments of the disclosed subject matter.

FIG. 3D schematically illustrates a 3D structure that can be used in the agriculture field as roofs of greenhouse, in animal farming, or in skylight, in accordance with some exemplary embodiments of the disclosed subject matter.

FIG. 3E schematically illustrates a 3D structure, comprising a thin sheet of a material that can be transparent or not, in animal farming, or in skylight, in accordance with some exemplary embodiments of the disclosed subject matter.

FIG. 3F schematically illustrates a cross-sectional view of a flexible array of prisms, in its rolled state, in accordance with some exemplary embodiments of the disclosed subject matter.

FIG. 3G(i) schematically illustrates an isometric view of a flexible array of prisms, deployed on a surface, in accordance with some exemplary embodiments of the disclosed subject matter.

FIG. 3G(ii) schematically illustrates a cross-sectional view of a flexible array of prisms, deployed on a surface, showing some path of rays, in accordance with some exemplary embodiments of the disclosed subject matter.

FIG. 3H(i) schematically illustrates an isometric view of a semi-transparent shell, in accordance with some exemplary embodiments of the disclosed subject matter.

FIG. 3H(ii) schematically illustrates an isometric view of a semi-transparent shell, in accordance with some exemplary embodiments of the disclosed subject matter.

FIG. 4A, schematically depicts an electricity producing industrial building having at least one flexible array of triangular shells installed, in accordance with some exemplary embodiments of the disclosed subject matter.

FIG. 4B, schematically depicts an electricity producing industrial building having prefabricated solar structural elements, in accordance with some exemplary embodiments of the disclosed subject matter.

FIG. 5A schematically illustrating a photograph view of a prefabricated solar elements having tilted solar strips, in accordance with some exemplary embodiments of the disclosed subject matter.

FIG. 5B schematically illustrating a photograph view of a prefabricated solar elements having shallow tilted solar strips, in accordance with some exemplary embodiments of the disclosed subject matter.

FIG. 6A schematically illustrates a photograph view of a prefabricated semi-transparent solar element having solar stripes, in accordance with some exemplary embodiments of the disclosed subject matter.

FIG. 6B schematically illustrates a photograph view of a prefabricated semi-transparent solar element having solar strips installed as a window, in accordance with some exemplary embodiments of the disclosed subject matter.

FIG. 6C schematically depicting a solar 3D construction that can be used in greenhouses or skylights, in accordance with some exemplary embodiments of the disclosed subject matter.

FIG. 6C schematically illustrates a photograph view of a mold used for molding the 3D solar construction, in accordance with some exemplary embodiments of the disclosed subject matter.

FIGS. 7A(i) to 7A(ii) schematically illustrate solar fences of different types provided with solar cells in accordance with an embodiment of the disclosed subject matter.

FIG. 8A schematically illustrates roofing material according to the Prior art.

FIG. 8B schematically illustrate solar cells attached to corrugated roofing materials, in accordance with an embodiment of the disclosed subject matter.

FIG. 8C schematically illustrates corrugated roofing materials, having facets in different orientations, in accordance with an embodiment of the disclosed subject matter.

FIG. 9 schematically illustrates a 3D solar panel attached to a vehicle, in accordance with an embodiment of the disclosed subject matter.

FIG. 10A schematically illustrates the damage caused to solar cells when gluing them to a support structure, according to the prior art.

FIG. 10B schematically illustrates molds used in adhering solar cells, in accordance with an embodiment of the disclosed subject matter.

FIG. 10C schematically illustrates a 3D mold used in adhering solar cells, in accordance with an embodiment of the disclosed subject matter.

FIG. 10D schematically illustrates a 3D mold and a 3D rigid support structure, in accordance with an embodiment of the disclosed subject matter.

FIG. 10E schematically illustrates a soft pressure applying device, in accordance with an embodiment of the disclosed subject matter.

### DETAILED DESCRIPTION

Before explaining at least one embodiment of the disclosed subject matter in detail, it is to be understood that the disclosed subject matter is not limited in its application to the details of construction and the arrangement of the components set forth in the following description or illustrated in the drawings. The disclosed subject matter is capable of other embodiments or of being practiced or carried out in various ways. Also, it is to be understood that the phraseology and terminology employed herein is for the purpose of description and should not be regarded as limiting. The drawings are generally not to scale. For clarity, non-essential elements were omitted from some of the drawings.

The terms “comprises”, “comprising”, “includes”, “including”, and “having” together with their conjugates mean “including but not limited to”. The term “consisting of” has the same meaning as “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this disclosed subject matter may be presented in a range format. It should be understood that the description in range format is merely for convenience and brevity and should not be construed as an inflexible limitation on the scope of the disclosed subject matter. Accordingly, the description of a range should be considered to have specifically disclosed all the possible sub-ranges as well as individual numerical values within that range.

It is appreciated that certain features of the disclosed subject matter, which are, for clarity, described in the context of separate embodiments, may also be provided in combination in a single embodiment. Conversely, various features of the disclosed subject matter, which are, for brevity, described in the context of a single embodiment, may also be provided separately or in any suitable sub-combination or as suitable in any other described embodiment of the disclosed subject matter. Certain features described in the context of various embodiments are not to be considered essential features of those embodiments, unless the embodiment is inoperative without those elements.

In discussion of the various figures described herein below, like numbers refer to like parts. Specifically, a numeral followed by a letter such as “a” or “b” may mark symmetrical elements. So as to not clutter the text, a numeral followed by the letter “x” will refer to any of the letters that follow that numeral in the drawing, for example 10x can stand for any of 10a and 10b, 10A, etc.

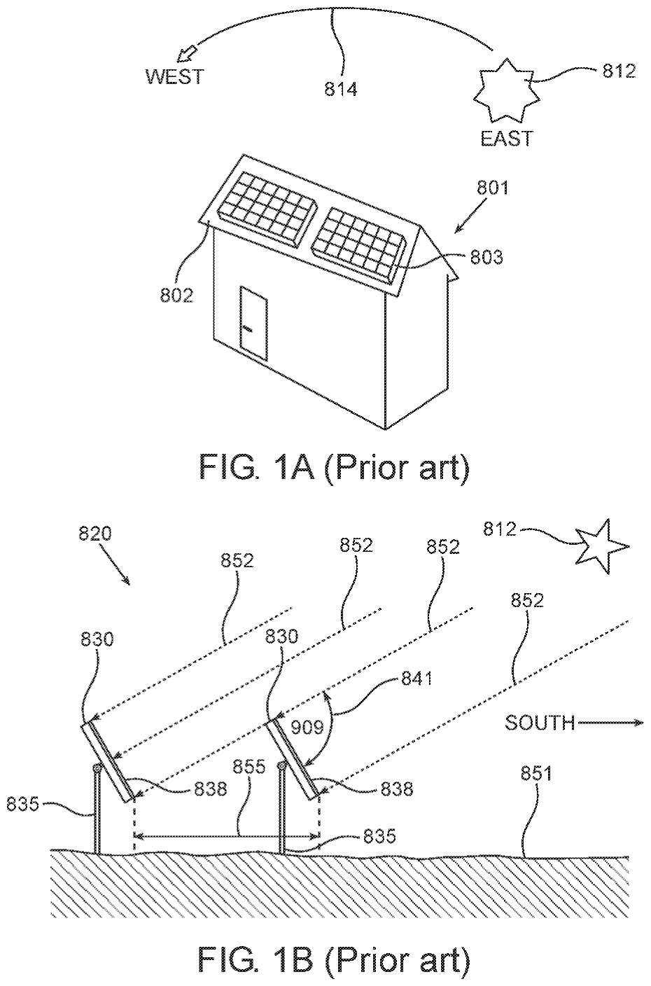

Reference is now made to FIG. 1A schematically depicting a house with solar panel constructions installed on its roof relative to the sun trajectory according to the prior art.

A house, or other structure such as 801 is illustrated to have a slanted roof 802 onto which a construction is built with solar panels 803. The construction itself is heavy and its installation is cumbersome and expensive. The sun 812 is travelling during the day in a trajectory 814 from the east to the west and the solar panel has to be installed on the roof preferably in an angle that is directed to the south, so as to effectively maximize the effective collection of light radiation. This markedly limits the areas onto which the solar panels can be installed in order to work effectively. In some cases, in order to get the correct angle towards the south, a metal construction is built beneath the main construction with the solar cells. This adds to the cost of the energy generation system.

Another limitation of prior art solar panels is that the solar cells are encapsulated within the construction that blocks light from passing through. In case the roof has skylight, windows or openings, this limits the area onto which the panels can be installed since it nulls the skylight or any other openings on the roof. Moreover, there are roofs that needs to be able to allow sunlight to pass through the roof, and thus a construction as shown in FIG. 1 cannot be used in such cases since they block the sun light. Some roofs are not sturdy enough to support solar constructions of the prior art.

As not all houses are built with optimally slanted or oriented roof, the efficiency of the energy collection may be compromised. It should be noted that the efficiency of the energy collection is compromised while the sun is changing its location in the sky during the day (in any location) and during the year (away from the equator).

Reference is now made to FIG. 1B schematically depicting a solar panel array construction installed on a horizontal surface, relative to the sun trajectory, according to the prior art.

Solar array 820 comprises a plurality of flat solar panels 838 (seen here from the side), each installed on a support construction surface 830, that is installed on a corresponding support structure 835. In order to optimize the energy generation, the panels are oriented such that the angle 841 between the sun rays 852 and the surface of the solar panels 838 is close to 90 degrees when the sun 812 is at its highest position. To avoid shadowing of one panel by the adjacent one, the distance 855 between adjacent panels needs to be maintained. This causes gaps between adjacent panels, and incomplete coverage of the surface 851 on which the array 820 is positioned. In large solar arrays, surface 851 is the ground, while in smaller arrays, surface 851 may be a rooftop. As the sun moves in its daily and seasonally trajectories, shadowing and/or unused gaps between panels are unavoidable.

Seasonal adjustment of the tilt of panels 838 requires periodic tilting the orientation of the support surface 830 in respect to the structure 835. This adds to complexly and cost to the solar system as well as increases the maintenance cost.

Since the support surface 830 is opaque, sunlight, direct or scattered, cannot pass through it to illuminate the solar panels 838 from behind.

It should be noted that “dual-sided” solar cells, designed to produce electricity if illuminated on either side, are available. However, these are costly. Solar panels designed for one-sided illumination do generates electricity (at lower efficiency) when illuminated from their back side. However, in a conventional solar panel, having opaque support surface, back illumination is impossible.

Reference is now made to FIG. 1C, schematically depicting an industrial building, according to the prior art.

Industrial buildings 860 are often comprise prefabricated slabs 862 from which the walls 864 and/or roof 861 are constructed. Adding solar panels to such industrial building is usually accomplished by installing, on the roof 86, a solar array of the art, such as seen in FIG. 1B. This is specifically the case, as roofs of industrial buildings are often flat, and not tilted to the south as seen in FIG. 1A. The installation is very costly and complex. Additionally, the weight of the added solar array and the support constructions has to be considered, and reinforcing the roof may be needed. Some roofs cannot support the added weight at all, for example, roofs made of corrugated plastic or corrugated fiberglass material.

As the solar array 820 is mainly opaque, skylights in the roof are essentially shadowed by it.

Due to the high cost of installing solar arrays on the vertical walls, and the fact that the walls may not optimally face the sun, walls are rarely used for solar panels. It should be noted that simply covering vertical walls with flat solar panels is an inefficient use of the expensive solar cells due to unfavorable angle to the sun. It should be also noted that installing tilted solar panels on existing roofs, and more so on existing walls, is time consuming, expensive, requires engineering testing and/or complying with regulations, and is aesthetically displeasing.

It is an object of the present subject matter to provide solar constructions comprising three-dimensional features that overcome at least some of the shortcoming of prior art solar arrays seen in FIGS. 1A, 1B and 1C.

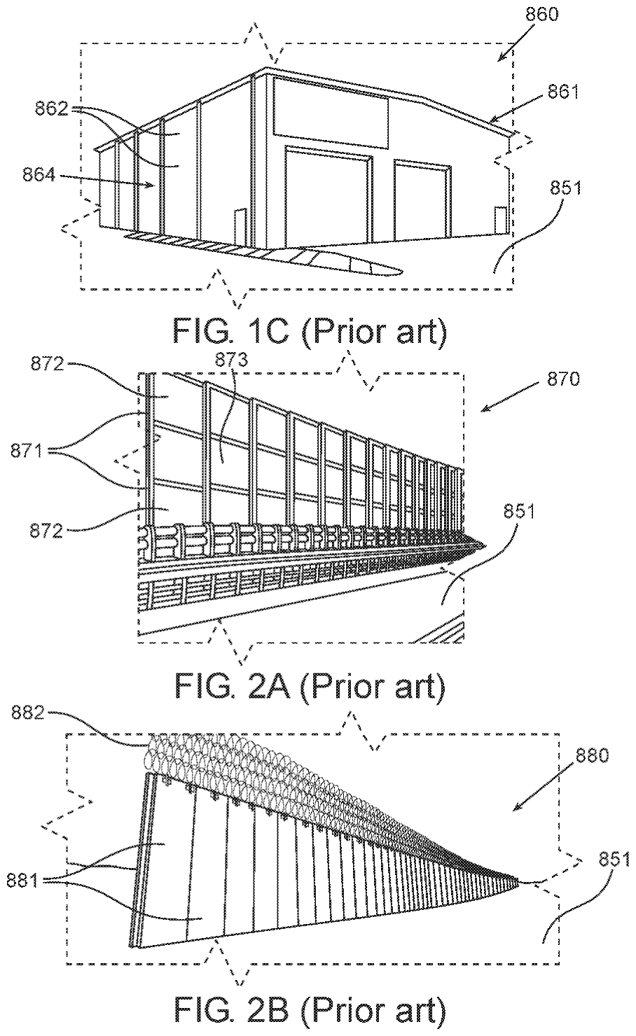

Reference is now made to FIG. 2A, schematically depicting an acoustic barrier according to the prior art.

Acoustic barriers such as seen in this figure are often constructed near and along train tracks or highways to decrease the noise level in nearby public or residential areas. Acoustic barrier 870 comprises frame structures 871 that are anchored to the ground 851. Transparent plates 872, and/or semi-transparent plates 871 are then attached to frame 871.

Since acoustic barriers must follow the nearby train track or highway, their orientation depends on the path of the train track or highway, and they cannot always be oriented facing the south. Thus, simply covering the vertical plats with flat solar panels is an inefficient use of the expensive solar cells. In east-west facing acoustic barrier, the efficiency of electricity generation is further reduced by the fact that in mid-day, the sun rays fall mainly parallel to the barrier. It should be also noted that installing tilted solar panels of the art on acoustic barriers is time consuming, expensive, and is aesthetically displeasing. Additionally, installing solar cells on large portion of the plates 871 and 872 greatly reduces the transparency of the barrier.

Reference is now made to FIG. 2B schematically depicting a security barrier according to the prior art.

Security barriers such as seen in this figure are often constructed near and along a border or around sensitive installation to provide small arms protection and intrusion deterrent. Security barrier 880 comprises a plurality of slabs 881 that are firmly anchored to the ground 851. Barbed-wire fence 882 is often installed on top of slabs 881.

Intrusion sensors such as surveillance cameras, motion detectors, proximity sensors, radars, search lights, a combination thereof, and the like are often installed on the security barriers. Such electronics devices require electricity, and since these security barriers are often in remote locations, providing electrical power from the main power grid is expensive and may be dangerous.

Since security barriers must follow the borders of the protected zone, their orientation depends on it, and they cannot always be oriented facing the south. Thus, simply covering the vertical slabs with flat solar panels is an inefficient use of the expensive solar cells. In east-west facing security barrier, the efficiency of electricity generation is further reduced by the fact that in mid-day the sun rays fall mainly parallel to the barrier. It should be also noted that in some cases, installing solar cells on the side of the security barrier facing away from the protected zone, such as the border may expose it to enemy fire or vandalism.

It is another object of the present subject matter to provide a solar construction comprising a three-dimensional that overcome at least some of the shortcomings of solar electricity generation from barrier such as seen in FIGS. 2A, and 2B.

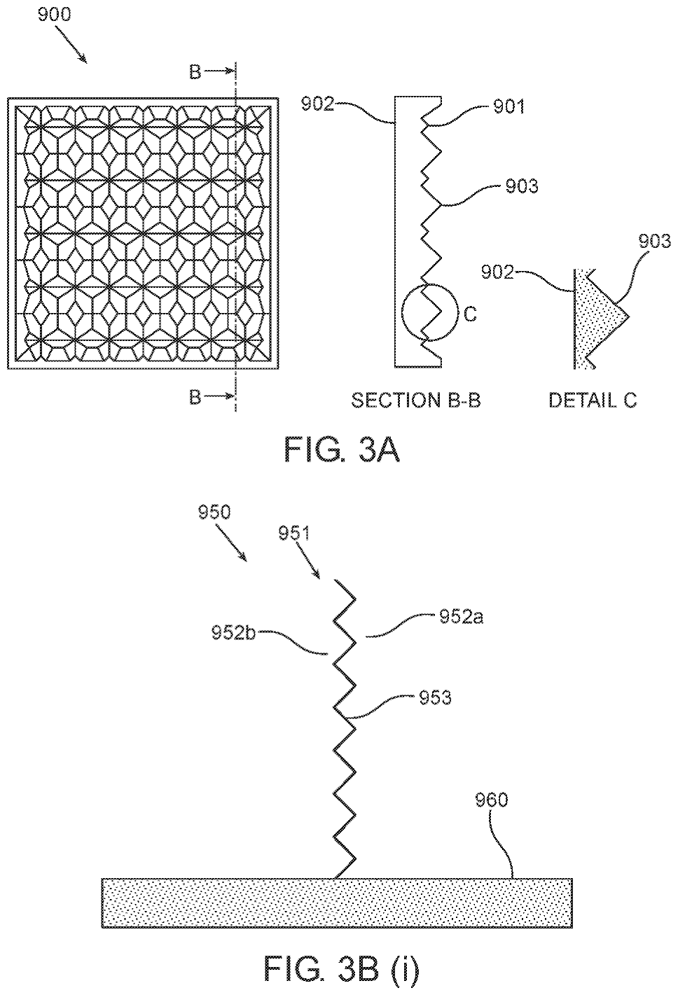

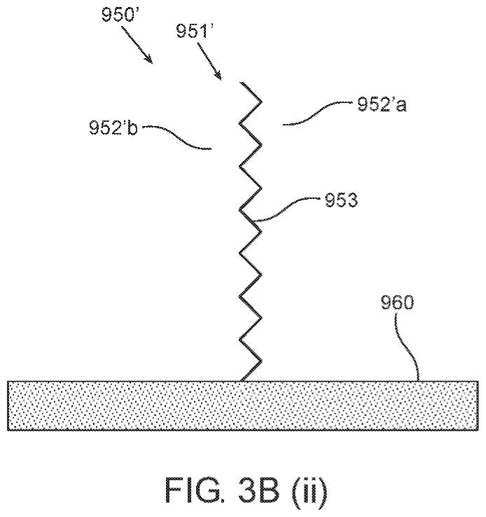

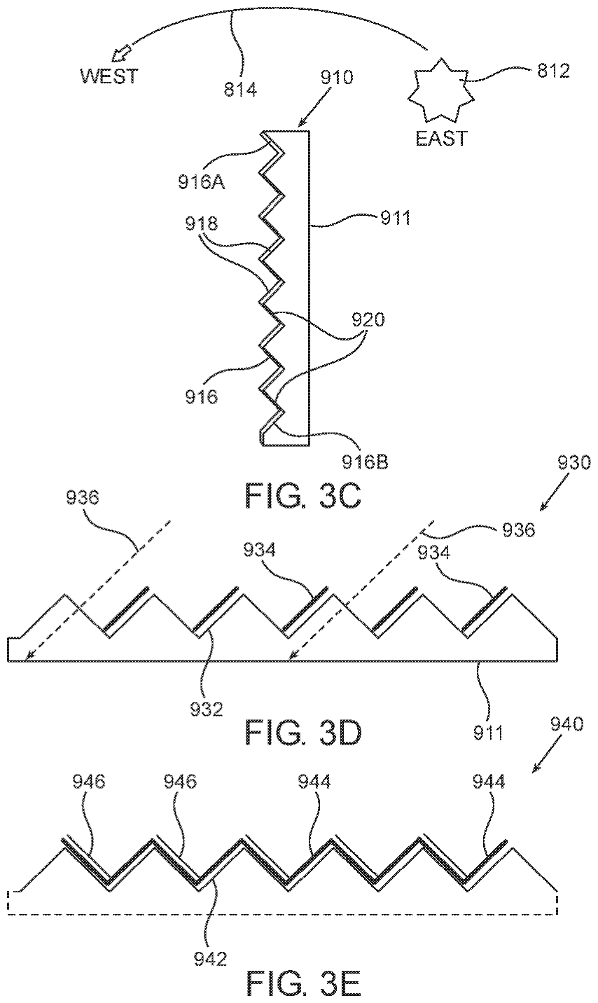

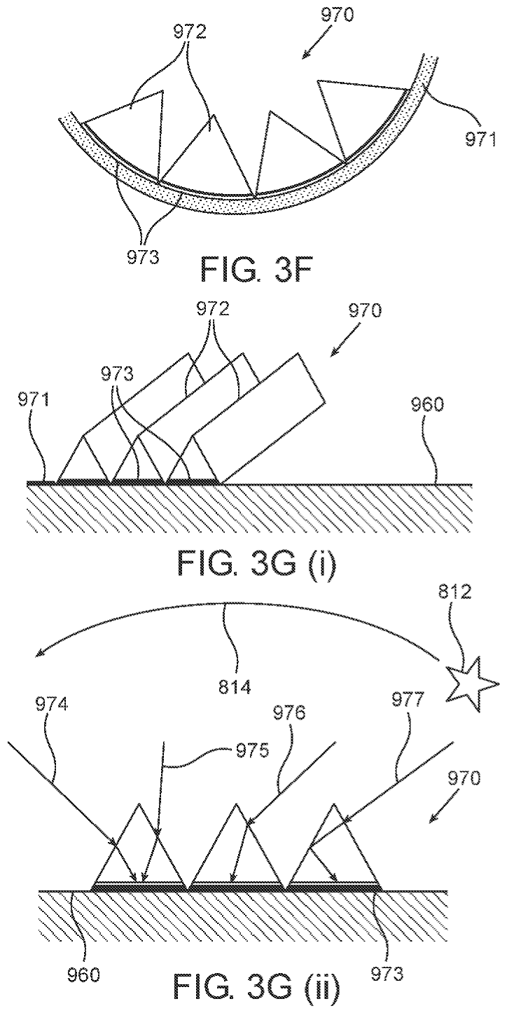

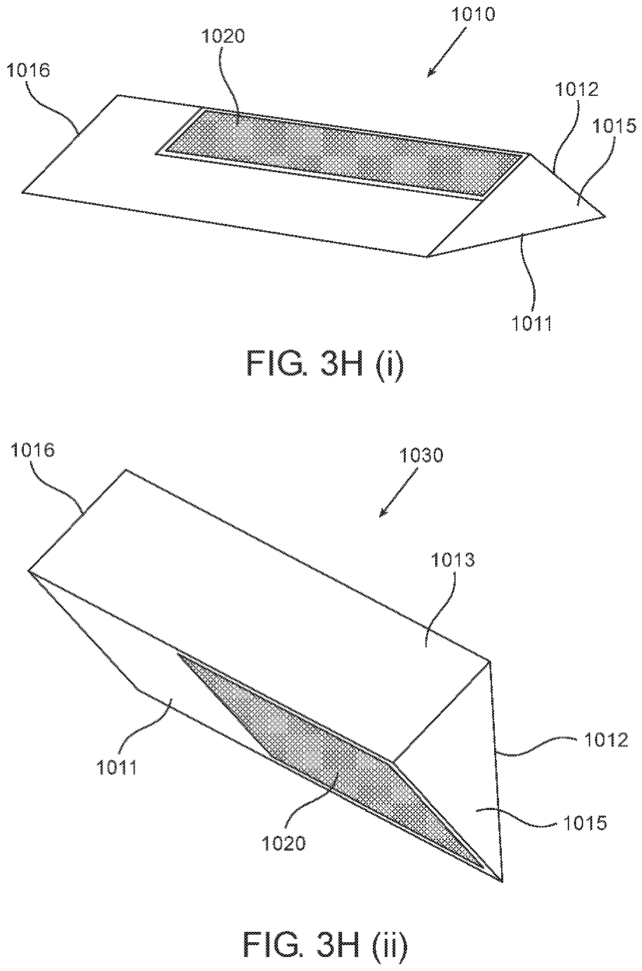

FIGS. 3A to 3H(ii) discloses some efficiency enhanced solar energy units and systems that uses 3D surfaces or prisms that can be used in architectural structures, and allow overcoming at least some of the abovementioned shortcomings.

Referring now to FIG. 3A schematically illustrating different types of surfaces to be provided with solar cells in accordance with embodiments of the disclosed subject matter.

Different shapes of surfaces having 3D structure, having sides that are oriented in many directions, can be used, with the solar cells provided on some of the sides, optionally using transfer of light within the structure.

The structure 900 can be a bulk or a shell 901 onto which the solar cells are adhered or embedded within. The face of the structure can be seen as well as a cross sectional views (B), and the enlargement (C), showing the many sides of the structure and their depth.

Vertically oriented structures containing prismatic or angulated structures such as disclosed in this document can be used as solar fences that combine solar energy generation with a physical barrier.

The geometric shapes increase the area of the solar cells up to three times compare to the area of structure 900; thus the fence gives higher light utilization than a standard panel because it has both more space of solar cells, and optionally it acts as double-sided.

Referring now to FIG. 3B(i) schematically illustrating a cross sectional view of a solar fence in accordance with embodiments of the disclosed subject matter.

The solar fence 950 is seen in this example anchored vertically to the ground 960. In the cross-sectional view of solar fence 950, it can be seen how the panel 951 is made of two transparent plastic or glass panels 952a and 952b in a three-dimensional shape while between the two panels 952a and 952b, there is provided double-sided solar cells sheet 953 that receives light from both sides of the fence and thus, more hours of exposure to light are possible. The fence will receive more hours of sunshine than a regular panel because it receives sunlight all day even when the sun is in the east, the sun is in the south, and also when the sun is in the west.

The fence provides good solution for places where it is not appropriate to put ordinary panels, such as roadsides, along railway tracks, near charging points for electric vehicles, at agricultural fields, and any place where there is not enough space to put ordinary panels.

The solar fence can be partially transparent, or have parts that are transparent or semitransparent, a combination thereof. The solar fences can be installed within agricultural areas, as a separation fences in roads, walls, acoustic walls, near electrical public transportation, in the vicinity of electrical vehicles charging, sports facilities, and the like, to provide physical structural benefits as well as providing solar power.

It should be noted that the solar cells are embedded between the two-sided fence, or adhered on one side of the fence. The two-sided fence takes advantage of the sunlight in any orientation.

The transparent materials used in the solar fences can be polycarbonate, PVC, acryl, glass, a combination thereof, and the like. These vertical structures provide more exposed surfaces in a relatively small area on the ground.

It should be noted that the energy production of the solar cells can be performed in corrugated and differently oriented surfaces. Another advantage of the solar fences having structured face is their lack or reduced reflection of sunlight, and car headlight towards the people that are using the roads.

Additional advantage of the structured face of the solar fence seen herein is its sound absorption properties. Unlike a flat surface that mainly reflects sound, structured surface disperses and absorb soundwaves.

Referring now to FIG. 3B(ii) schematically illustrating a cross sectional view of a solar fence providing improved ballistic protection, in accordance with other embodiments of the disclosed subject matter.

The solar fence providing improved ballistic protection 950′ is seen in this example, anchored vertically to the ground 960. In the cross-sectional view of solar fence providing improved ballistic protection 950′, it can be seen how the panel 951′ is made of two transparent plastic or glass panels 952′a and 952b′ in a three-dimensional shape while between the two panels 952′a and 952′b, there is provided double-sided solar cells sheet 953 that receives light from both sides of the fence and thus; more hours of exposure to sunlight are possible. However, a single-sided solar cells sheet can be used. Specifically, when the fence 950′ is installed along the east-west direction, sunlight is falling mainly on one of its sides. Additionally, some single-sided solar cells do generate electricity (at reduced efficiency) when illuminated on their back side. Generally, single-sided solar cells are cheaper than double-sided solar cells.

It should be noted that some of the prisms disclosed in this document provide two-sided operation to the energy collecting unit without the use of the more expensive double-sided solar cells. Moreover, while experiments show that the use of double-sided solar cells adds only 10% to 20% increased efficiency, the use of prisms can add up to 60% added efficiency. This is specifically important in countries where the sun is low in the sky.

All attributes and advantages of solar fence 950 and solar fence 950′ are same or similar.

However, panels 952′a and 952′b, are thicker than the corresponding panels 952a and 952b, and preferably, when combined to form the solar fence, provide improved ballistic protection 950′, they are interlocked to form a thick fence having essentially flat outer surfaces.

The solar fence providing improved ballistic protection 950′ can provide protection against small arms fire, blast, and fragmentation of explosive munition. Transparent sections, having no solar cells, can be included to allow observation while being partially obscured from enemy vision, and remaining protected. Firing portholes may also be included for the defenders. The thickness of the solar fence providing improved ballistic protection 950′ can be selected to provide the required strength and protection. Additional anti-blast plates or lamination can be added, for example on both sides, or on the venerable side only. The solar fence providing improved ballistic protection 950′ can be made of polycarbonate material that is strong and do not get shattered easily. The solar fence providing improved ballistic protection 950′ can be used in military installation, borders and places where vandalism is likely to occur. The solar fence providing improved ballistic protection 950′ can be used as a rugged solar energy generation system, not as part of a fence.

Reference is now made to FIG. 3C schematically illustrating a 3-dimensional solar structure, in accordance with some exemplary embodiments of the disclosed subject matter.

The sun 812 is seen travelling from the east to the west in a trajectory 814. A solar system 980 comprising a 3-dimensional solar structure 910 having a zigzag profile is vertically positioned. The area on the ground is minimal in oppose to the area of solar panels of the prior art occupies since the flat standard structure has to be positioned while the surface of the panel is directed upwardly. The current construction is vertical and therefore, occupies about approximately 5-10 percent of the surface of the prior art.

The zigzag profiled structure 916 is a relatively thin structure that comprises a first surface 916A that can be positioned faced to the west, as an example, and an opposite surface 916B that is substantially the same as the first surface, and positioned facing the east. Other directions are possible as well, and depend on the positioning of the structure.

The thickness of the thin structure can be from about 2 mm thick to a few centimeters or more. In the case where about 2-5 mm sheet is used, the width of the zigzag profile can be about 60 mm±5 mm. The angle between successive surfaces can be about 90 degrees and the distance between successive lows or highs can be about 125 mm±5 mm. However, other parameters can be used.

The zigzag profiled structure 916 can be positioned as a fence that separates or bound areas in private, municipal, or national uses. Solar cells 918 are attached on a first surface 916A on the faces that are upwardly directed. Solar cells 920 are attached to the opposite surface 916B and on the surfaces that are upwardly directed. In this way, while the sun is in the east, the solar cells 920 on the opposite surface 916B are active in producing electricity in the afternoon, when the sun travelled to the west, the solar cells 918 on the first surface 916A are active. In this way, although the structure 910 is vertically positioned and the area it occupies on the ground is minimal, the effectiveness of collecting the radiation coming from the travelling sun is maintained.

It should be mentioned that the 3D structure 910 is light relatively to the heavier constructions in the prior art, and can be as much as 50 percent lighter than the prior art structures. Therefore, its transportation is easy as well as its installation. Moreover, it can be placed in places where structures of reduced weight need to be used such as over water and on structures that are made of materials that are not strong but are cost effective.

It should be mentioned that not all the surfaces facing up need to be covered with solar cells, and the spread of the solar cells is according to the requirements of the system.

In accordance with another embodiment, only one side is covered with solar cells and the other side is used in order to adhere the 3D structure to cover a wall of any element that has vertical.

On surfaces facing the light, that are not covered by solar cells, mirrors can be glued (or the surface may be coated with reflective material), so as to increase the reflections of the light in the solar cells area and further increase their effectiveness during the day.

Reference is now made to FIGS. 3D and 3E schematically illustrating a 3-dimensional construction onto part of which or onto which solar cells are adhered, respectively, in accordance with some exemplary embodiments of the disclosed subject matter.

FIG. 3D illustrates a 3D structure 930 that can be used, for example, in the agriculture field as roofs of greenhouse, in animal farming, or in skylight, in accordance with some exemplary embodiments of the disclosed subject matter.

The thin structure 932 is made of a material that is transparent such as glass, polycarbonate, a combination thereof, or the like. The 3D structure 30 comprises a thin sheet 932 of transparent material having an upper surface in zigzag profile. The upper surface of the thin sheet 932 is partially covered with solar cells 934. The covered surfaces are the surfaces that are all facing to the same direction while the surface that faces the other directions are left uncovered. Since the thin sheet 932 is transparent, light can penetrate to the other side of the 3D structure 930. Light beams penetrate the roof structure 930 as shown by arrows 936.

In accordance with other embodiments, the thin sheet 932 can be transparent but pigmented so that the light passing through the transparent surfaces is colored. This can be used in certain crops that grow better in colored light.

In accordance with yet another embodiment, the transparent portions that are not covered by solar cells can be provided with light filters. Optionally, the transparent portions that are not covered by solar cells can be open or made of mash, or having holes for air circulation.

FIG. 3E illustrates a 3D structure 940 comprises a thin sheet 942 of a material that can be transparent or not. The whole upward facing surface is covered with solar cells. Solar cells 944 directed to a certain direction while solar cells 946 are facing to the opposite directions. Also in this case, in accordance with another embodiment, some of the surfaces can be covered with mirrors that merely reflects the light beams to the other direction instead of some of solar cells 944 and/or solar cells 946.

The 3D structure 940 can be used to cover warehouses, where light is not desirable to penetrate the structure through the roof. The same structure can be used also to cover the walls of the building or the warehouse.

It should be mentioned that there is no limit to the length or width of the 3D structure.

It should be emphasized that in some embodiments, the solar cells are adhered to, or embedded into the construction structure that will be used to construct roof or wall, rather than being embedded within a support construction that is later installed onto the existing roofs or walls as known in the prior art. This is one of the reasons why the 3D structure is lighter than the conventional structures.

Another shortcoming associated with prior art constructions is that the panels are getting very hot, and therefore, hot spots are formed on the solar cells that limits the effectiveness of the panels. Cooling of the panels is required, which is sometimes performed by sprinklers. This increases the cost and complexity of the solar system. According to some embodiments of the present subject matter, a solar panel is provided, that is incorporated in the roof so the air-condition from the interior of the warehouse or building cools the solar cells. This also keeps the solar cells more effective over time and reduce their degradation.

Another advantage of the present subject matter relative to the conventional solar panels is that the whole roof and/or wall can be covered with the solar cells since the direction of the panels is not limited to the south. Other directions are possible as well so the possibilities are greater.

FIGS. 3F, 3G(i) and 3G(ii) schematically illustrate a flexible array of prisms, in accordance with some exemplary embodiments of the disclosed subject matter.

Reference is now made to FIG. 3F schematically illustrating a cross-sectional view of a flexible array of prisms, in its rolled state, in accordance with some exemplary embodiments of the disclosed subject matter.

Flexible array of prisms 970 comprises a plurality of rigid or semi-rigid prisms 972, each with a solar cell 973 attached to its lower surface. The plurality of prisms 972 are then attached to a flexible sheet 971 that allows the flexible array of prisms 970 to be rolled for transportation or storage. Additionally, the flexibility of the flexible sheet 971 enables deploying it on curved surfaces (convex or concave). Flexible sheet 971 may be opaque, for example for deployment on a roof, or transparent for deployment on a transparent plate to be deployed as a partially transparent skylight, partially transparent window, or a solar fence. In these cases, semi-transparent solar cells are used, or not all the area of the flexible array of prisms is covered with solar cells.

Note that other type of prisms, for example as seen in other figures throughout this document can be used.

Reference is now made to FIG. 3G(i) schematically illustrating an isometric view of a flexible array of prisms, deployed on a surface, in accordance with some exemplary embodiments of the disclosed subject matter.

In this example, the flexible array of prisms 970 is unrolled and attached to a surface 960. Surface 960 can be a rooftop or a wall. Attachment can be done using adhesive or fasteners (not seen herein). Lage flexible array of prisms 970 can be cut to size in between two adjacent prisms. Large areas can be covered by a plurality of flexible array of prisms.

Reference is now made to FIG. 3G(ii) schematically illustrating a cross-sectional view of a flexible array of prisms, deployed on a surface, showing some path of light rays, in accordance with some exemplary embodiments of the disclosed subject matter.

As the sun 812 travels along its daily and seasonally path 814, the flexible array 970 (seen herein deployed on a horizontal surface, but tilted or curved surface may be used), can take advantage of rays arriving from any directions. To reduce cluttering of the figure, paths of rays that are reflected from one prism to the adjacent prism were omitted.

FIGS. 3H(i) to 3H(ii) schematically illustrating semi-transparent shell, in accordance with some exemplary embodiments of the disclosed subject matter. In some embodiment the prisms are hollow, and optionally are full of water.

Reference is now made to FIG. 3H(i) schematically illustrating an isometric view of a semi-transparent shell, in accordance with some exemplary embodiments of the disclosed subject matter.

Semi-transparent prism 1010 is having a bottom surface 1011, two side surfaces 1012 and 1013, and two ends 1015 and 1016.

In the depicted example, solar cell 1020 is attached to, and covers a portion of one of the side surfaces 1012 or 1013. This allows some of the light impinging on the semi-transparent prism 1010 to go through the semi-transparent prism. Thus, semi-transparent shell 1010 can be used, alone or in an array, as partially transparent roof, skylight, or window, a combination thereof, of the like.

Reference is now made to FIG. 3H(ii) schematically illustrating an isometric view of a semi-transparent shell, in accordance with some exemplary embodiments of the disclosed subject matter.

Semi-transparent shell 1030 is having a bottom surface 1011, two side surfaces 1012 and 1013, and two ends 1015 and 1016. In the depicted example, solar cell 1020 is attached to, and covers a portion of the bottom surface 1011. This allows some of the light impinging on the semi-transparent shell 1030 to go through the semi-transparent shell. Thus, semi-transparent shell 1010 can be used, alone or in an array, as partially transparent roof, skylight, or window.

It should be noted that the location, sizes and the portion of coverage of the solar cell 1020 seen herein are to be used as non-limiting examples, and other parameters can be used. Optionally, a plurality of solar cells can be used on the same shell, optionally on different surfaces. Alternatively, the solar cell can cover the entire surface.

One advantage of the rectangular solar cell seen in use with the elongated shells 1010 and 1030 is the ease of producing the solar cell patches 1020. Solar cells are usually procured as large sheets that are cut to size. The large solar sheets are often pre-grooved so they can easily be cut to rectangular shaped patches. In contrast, cutting triangular, or other shapes having non-right-angles shaped patches can be difficult and can cause waste of solar cell material. Up to 50% loss of solar cell material can be caused when cutting octagonal patches.

Optionally, the elongated shells are made as hollow shells, having their two ends 1015 and 1016 open. On deployment, the hollow shells can be filled with water. Since the index of refraction of water is close to the index of refraction of plastic and glass, the water filled shell has similar optical properties of a solid prism. The prismatic shells can be produced by extrusion, they are lighter to transport, and are cheaper due to the low cost of water compared to glass or plastic.

Additionally, the hollow shells can be used to conduct a flow of water from one end to the other. The flow of water can be used for cooling the solar cells, thus increasing their efficiency.

Additionally, and optionally, the hollow shells with water circulation or flow, can be used as part of solar collector for solar hot water system, providing both electricity and hot water at the same time.

In High-rise buildings, the rooftop may be too small for installing solar heat collectors for all the apartments, and the hot water may get cold on its long way from the roof to the lower floors. In these cases, the water-filled solar shells can be installed on the wall facing the sun, providing hot water directly to the apartments, and providing electricity at the same time.

Alternatively, the hollow shells are left empty and optional holes are drilled in at least one of their surfaces to allow air circulation or flow for cooling the solar cells.

In applications where only one side of the shells is exposed to the sun, metallic plate, (for example aluminum), optionally having heat-sink fins exposed to the air, can be used.

Up to 18% efficiency and 50% light transmission may be achieved with these semi-transparent light shells.

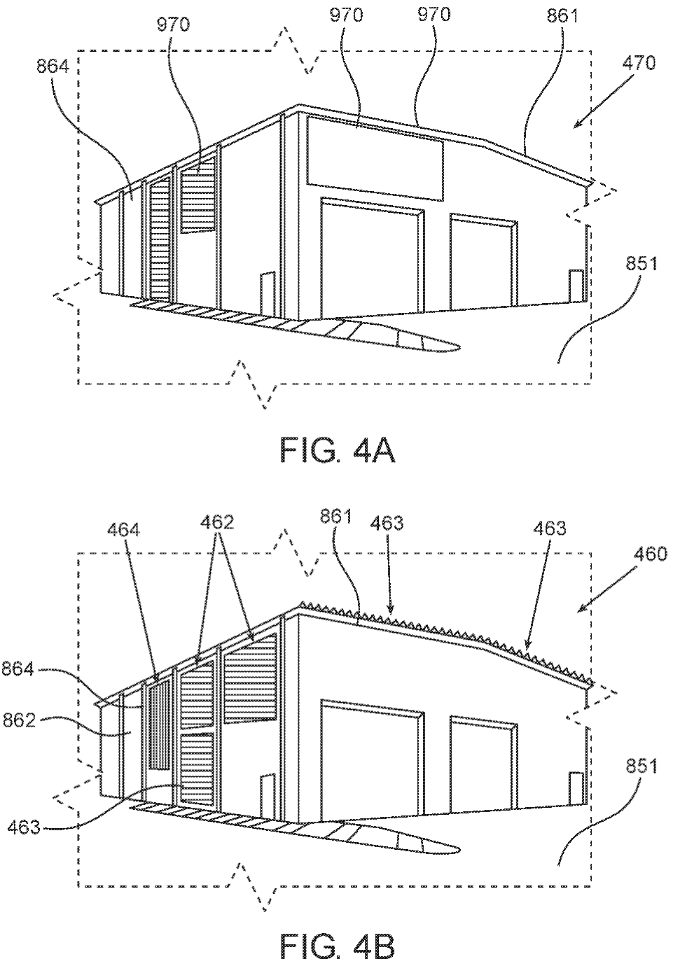

FIGS. 4A and 4B disclose industrial buildings with solar generation capabilities that overcome at least some of the shortcomings associated with the prior art seen in FIGS. 1A to 1C, in accordance with some exemplary embodiments of the disclosed subject matter.

Reference is now made to FIG. 4A, schematically depicting an electricity producing industrial building having at least one flexible array of triangular prisms installed, in accordance with some exemplary embodiments of the disclosed subject matter.

Flexible array of triangular prisms 970 can be placed on the roof 861 of the electricity producing industrial building 470. The light weight flexible array of the triangular prisms 970 requires no supporting structures and can be glued or fastened directly to the roof. Flexible array of triangular prisms 970 can be transported in its rolled state to be unfurled in-situ.

Additional flexible arrays of triangular prisms 970 can easily be attached to the walls 864 of the electricity producing industrial building 470.

Flexible arrays of triangular prisms 970 can cover entire wall, or roof, or it can cover parts of the walls. Specifically, walls facing away from the sun need not be covered with flexible arrays of triangular prisms. It can optionally be desired to keep the walls clear of flexible arrays of prisms near the ground 851, so as to prevent tampering with the arrays, or damage to the array by activity near the building.

It should be noted that while the example seen herein was demonstrated for an industrial building, residential buildings may also be fitted with flexible arrays of triangular prisms.

Reference is now made to FIG. 4B schematically depicts an electricity-producing modular industrial building, having prefabricated solar structural elements, in accordance with some exemplary embodiments of the disclosed subject matter.

In accordance with some exemplary embodiments of the disclosed subject matter, and in order to overcome the difficulties of converting industrial building to electricity-producing buildings, prefabricated structural elements are produced, that combines structural and solar cells as one integrated unit.

The sizes, strength, thermal isolation, and other parameters of the prefabricated solar elements 462 and 463 can be similar or identical to commercially available prefabricated slabs 862 from which the walls 864 and/or roof 861 of the industrial building 860 is constructed, with the addition of electrical connectors or wires for connecting to an electric generation controller unit. Thus, it is easy to exchange a prefabricated slabs 862 with the corresponding solar elements 462.

Alternatively, the modular industrial building 460 can be constructed from the start using solar roof elements 463 and/or solar wall elements 462. Roof elements 463 and/or solar wall elements 462 can be combined with conventional prefabricated slabs 862 and non-solar roof units, or integrated with conventional building techniques such as carpentry, brickwork, concrete, a combination thereof, and the like. Similarly, solar roof elements 463 and/or solar wall elements 462 can be integrated within residential, offices and high-rise buildings.

Electric generation controller units of the art can be used, and will not be discussed further in this document.

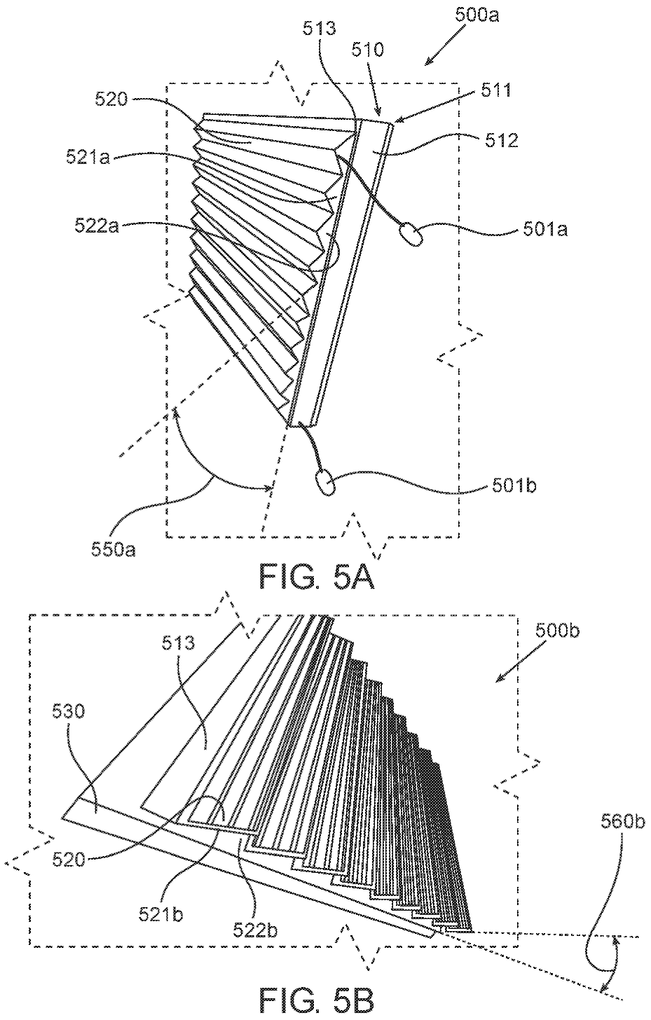

FIGS. 5A to 5B schematically illustrate prefabricated solar elements 500a and 500b respectively, in accordance with some exemplary embodiments of the disclosed subject matter.

Prefabricated solar elements 500a and 500b differ by the tilting of the solar cells in order to optimize the efficiency as discussed hereinabove. Prefabricated solar elements 500a and 500b can be used as roof solar elements and/or wall solar elements.

Reference is now made to FIG. 5A schematically illustrating a photograph view of a prefabricated solar construction element 500a having tilted solar strips, in accordance with some exemplary embodiments of the disclosed subject matter.

Prefabricated solar construction element 500a comprises a structural slab 510, comprising an inner plate 511 and an outer plate 513, and a thermal isolation layer 512 sandwiched in between. On the outer plate 513, there are plurality of solar cells carrier 521a on which solar cell strips 520 are attached. Carries 521a are preferably made of light weight, thermally conducting material such as aluminum. However other metals (such as copper or iron sheet), or plastic, a combination thereof, or the likes, can be used. Optional cavitied 522a between the carrier 521a and the outer plate 513 enable cooling air circulation to reduce overheating of solar strips 520. The angles 550a of the carriers 521a to the outer plate 513 can be selected for energy production optimization as disclosed hereabove. In this non-limiting example, angles 550a of the carriers 521 a relative to the outer plate 513 is about 45 degrees.

Alternatively, the outer plate can be formed as a zig-zag plate and the solar strips 520 can be attached to it directly. Electrical cable or electrical connector 501a and optional electrical cable or electrical connector 501b are used for connecting the solar strips 520 of the prefabricated solar element 500a to adjacent prefabricated solar elements, or to an electric generation controller unit.

Reference is now made to FIG. 5B schematically illustrating a photograph view of a prefabricated solar construction element 500b having shallow tilted solar strips, in accordance with some exemplary embodiments of the disclosed subject matter.

Prefabricated solar element 500b differ from prefabricated solar element 500a in the shallower angles 550b of the carriers 521b to the outer plate 513. Thus, the cavities 522b between the carrier 521b and the outer plate 513 are narrower.

In this non-limiting example, angles 550b of the carriers 521b relative to the outer plate 513 is about 25 degrees.

Also seen in this figure are the optional structural interface 530 that allows joining the prefabricated solar element 500b to the building's frame or to adjacent prefabricated element. Similar optional structural interface to allow joining the prefabricated solar element 500b to the building's frame or to adjacent prefabricated element is not seen in these figures.

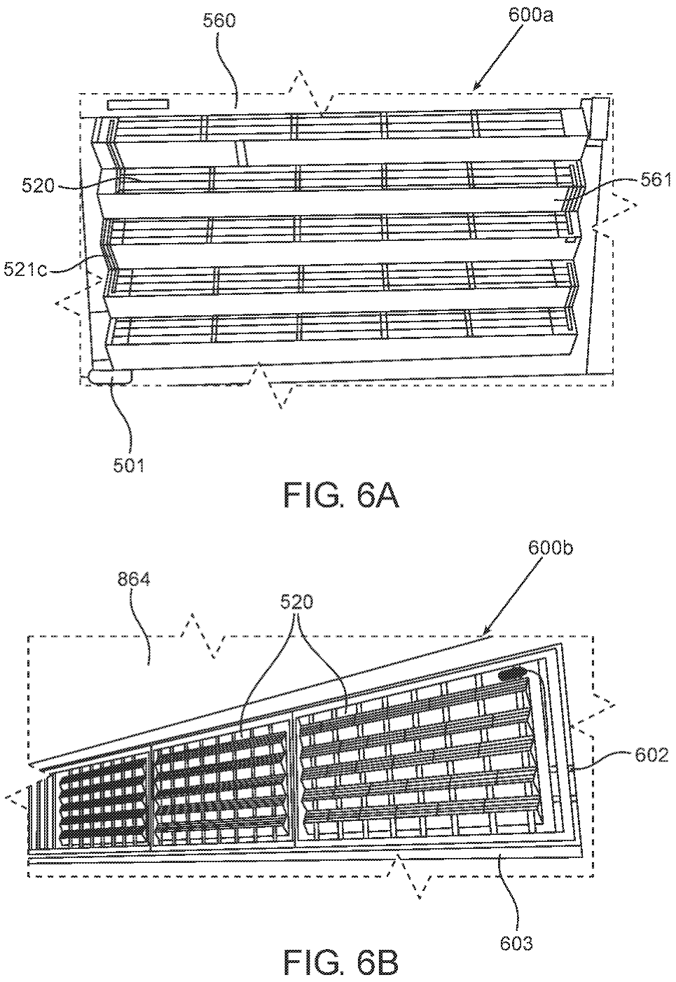

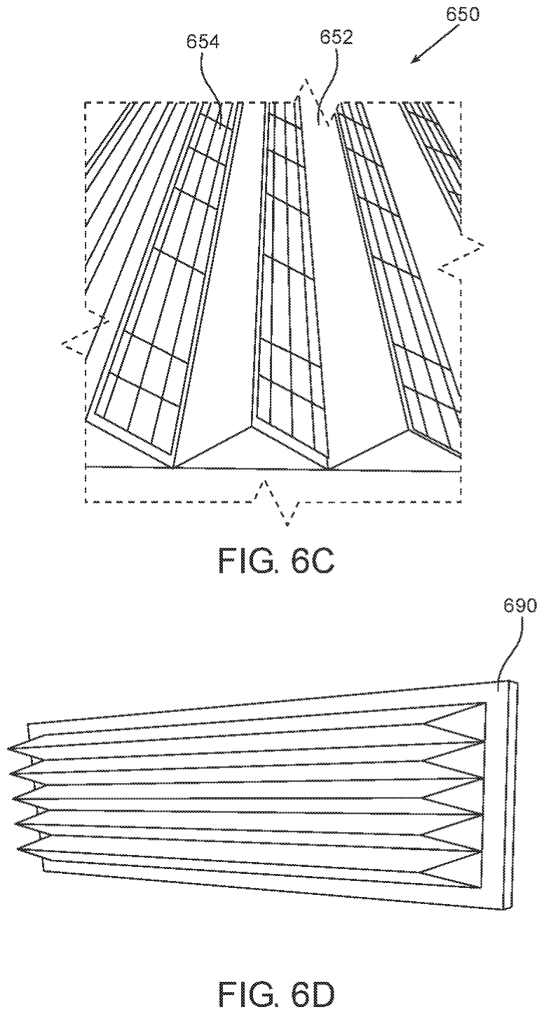

FIGS. 6A to 6C schematically illustrate prefabricated semi-transparent solar element, in accordance with some exemplary embodiments of the disclosed subject matter.

Reference is now made to FIG. 6A schematically illustrating a photograph view of a prefabricated semi-transparent solar element 500a having solar strips, in accordance with some exemplary embodiments of the disclosed subject matter.

Prefabricated semi-transparent solar element 600a differ from prefabricated solar elements 500a/b by the fact that transparent plate 560 replaces the structural slab 510, that comprises an inner plate 511 and an outer plate 513, and a thermal isolation layer 512 sandwiched in between. Optionally, for extreme weather conditions, transparent plate 560 can be of a double-glazed structure to provide better thermal insulation. Prefabricated semi-transparent solar element 600a can be used as windows, skylight, a combination thereof, and the likes.

Reference is now made to FIG. 6B schematically illustrating a photograph view of a prefabricated semi-transparent solar element 600b having solar strips, installed in a wall as a window, in accordance with some exemplary embodiments of the disclosed subject matter.

Prefabricated semi-transparent solar element 600b is seen herein installed as a window in wall 864. Optionally semi-transparent solar element 600b can be rotated about pivot or hinges 602 in window frame 603 from the closed state it is seen, to an open state. Other windows' frames and hinges can be used.

Reference is now made to FIG. 6C depicting a solar 3D construction that can be used in greenhouses or skylights, in accordance with some exemplary embodiments of the disclosed subject matter.

The 3D solar construction 650 comprises a transparent sheet of transparent material, in this case polycarbonate. The polycarbonate is transparent, so the structure can be used in greenhouses, as an example. The construction 650 is made of a zigzag profile in which there are successive surfaces one directed to one side and the other is directed to the other side. Surfaces that are directed to one side can be covered by adhered solar cells 654 and the other surface 652 facing in opposite direction stay intact and transparent. In this way, half of the surface of the roof, skylight, or window is producing electricity while the other half is transparent allowing light beam to pass through the roof.

It should be mentioned that one can determined how much of the surface is to be covered, and how much will be left intact, in accordance with the needs of the system.

As mentioned herein before, the transparent sheet can be made in colors so that if it is indeed used in a greenhouse, the light that gets into the greenhouse and reaches the crops can be partially or fully colored in case the crops grow better in those circumstances.

It should be mentioned that the zigzag profile shown herein is an example only and other surfaces of three dimensions can be implemented, such as pyramids.

It should be mentioned that the zigzag profile can be different in different areas of the sheet forming the structure, so that in a single sheet, several angles of the zigzag profile ban be presented.

It should be understood that different colors of solar cells can be adhered on the surfaces or on portions of the surfaces, and that colored or pigmented semi-transparent materials can be used.

As an example, in the depicted embodiment, the 3D solar construction 650 is molded, forged, or vacuum formed as a single piece of transparent plastic on which the solar strips 654 are attached.

Reference is now made to FIG. 6D schematically illustrating a photograph view of a mold 690 used for molding the 3D solar construction 650, in accordance with some exemplary embodiments of the disclosed subject matter.

The transparent the 3D solar construction 650 seen in FIG. 6C can be formed in mold 690.

As was noted throughout this document, tilting angles of the solar cells can be adopted to the local conditions. For example, in north Europe, the sun only reaches 55 to 60 degrees over the horizon in mid-day, an angle in which the solar cells are attached, of 50 to 60 degrees can be suitable for these locations.

For example, in central Europe, the sun only reaches 65 to 70 degrees over the horizon in mid-day, an angle in which the solar cells are attached of 35 to 45 degrees can be suitable.

For example, in Israel the sun reaches 80 degrees over the horizon in mid-day, an angle in which the solar cells are attached of 20 to 30 degrees can be suitable.

For example, in China, where the sun may reach 95 degrees over the horizon in mid-day, an angle of lower surface of the structure, where the solar cells are attached, of 20 to 30 degrees can be suitable.

For example, in New York, where the sun may reach 72 degrees over the horizon in mid-day, an angle of lower surface of the structure, where the solar cells are attached, of 35 to 45 degrees can be suitable.

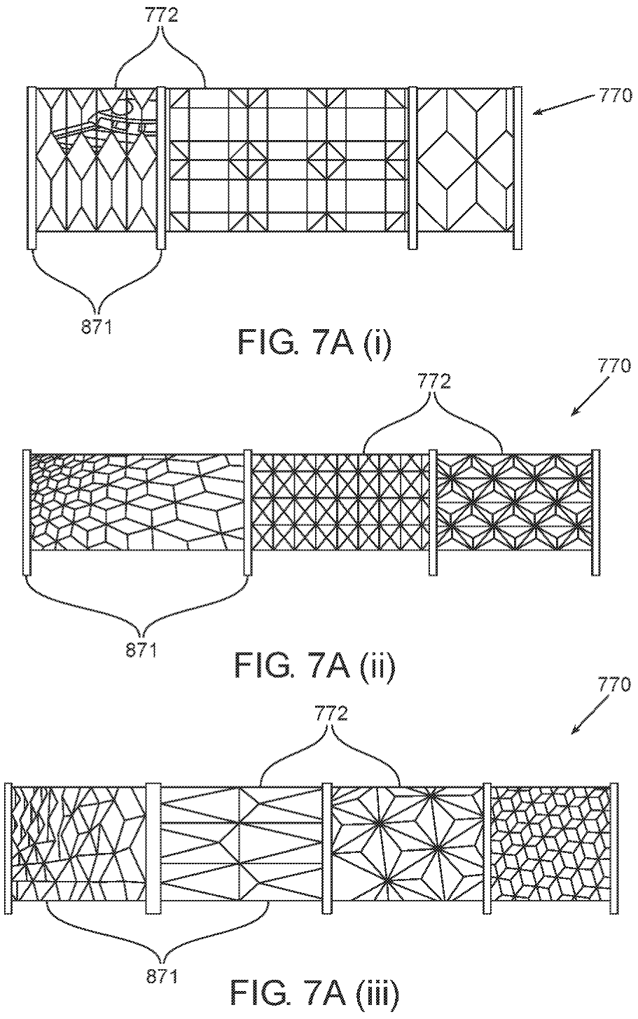

Referring to FIGS. 7A(i) to 7A(ii) schematically illustrating solar fences of different types provided with solar cells, in accordance with an embodiment of the disclosed subject matter.

The solar fence 770 is placed vertically to the ground, for example, using frame structures 871 and is provided with a plurality of tops and surfaces 772 that increase the surface area that is directed towards the sun light. This compensates the vertical positioning that is not as efficient as positioning solar cells towards the light source (in this case, the sun). The fence can be transparent, semitransparent, opaque, or a combination of transparent, semitransparent, and/or opaque sections.

The solar fences can be installed within agricultural areas, separation fences in roads, walls, acoustic walls, electrical public transportation, in the vicinity of electrical vehicles charging spots, and the likes.

It should be noted that the solar cells are embedded within a fence, or adhered on one side of the fence. Two-sided or a one-sided fence can be used. The two-sided fence takes advantage of the sun light in any orientation. Optionally the tops surface of the solar fences are provide with solar cells (not seen in these figures).

The materials from which the fences are made of can be polycarbonate, PVC, acryl, glass, a combination thereof, and the likes. These structures that are vertical provides more exposed surfaces in a relatively small area on the ground.

It should be noted that the production of the solar cells can be performed in corrugated and different oriented surfaces.

Another advantage of the structured solar fences is their reduced or lack of light reflection towards the people that are using the roads due to the structured face of the solar fence. Additional advantage of the structured face of the solar fence seen herein is its sound absorption properties. Unlike a flat surface that mainly reflects sound, structured surface disperses and absorb soundwaves.

Different types of surfaces having tops and sides that are oriented in many directions, and the solar cells can be provided on some of the sides while using the transfer of light within the structure. The structure can be a bulk or a shell onto which the solar cells are adhered, or embedded within.

Solar fences can be designed in different three-dimensional geometric shaped, and built of two transparent or semi-transparent plates of plastic or glass with double-sided solar cells between them as seen for example in FIGS. 3B(i) and/or 3B(ii) or any other 3D designs disclosed herein.

The geometric shapes increase the effective area of the solar cells up to three times the surface area of the solar fence, and thus the fence gives higher light utilization than a standard panel because it has both more space of solar cells and it can work as double-sided.

The fence can receive more hours of sunshine than a regular panel because it gets sun all day: when the sun is in the east, when the sun is in the south, and also when the sun is in the west. The fence provides good solution for places where it is not appropriate to put ordinary panels, such as roadsides, sides of railway tracks, charging points for electric vehicles, agricultural fields and any place where there is not enough space to put ordinary panels.

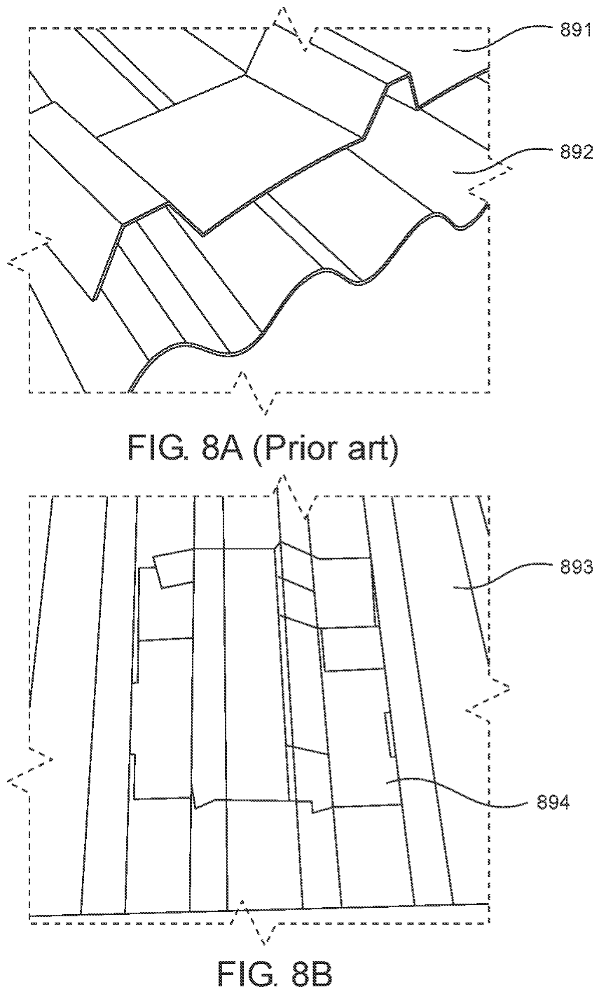

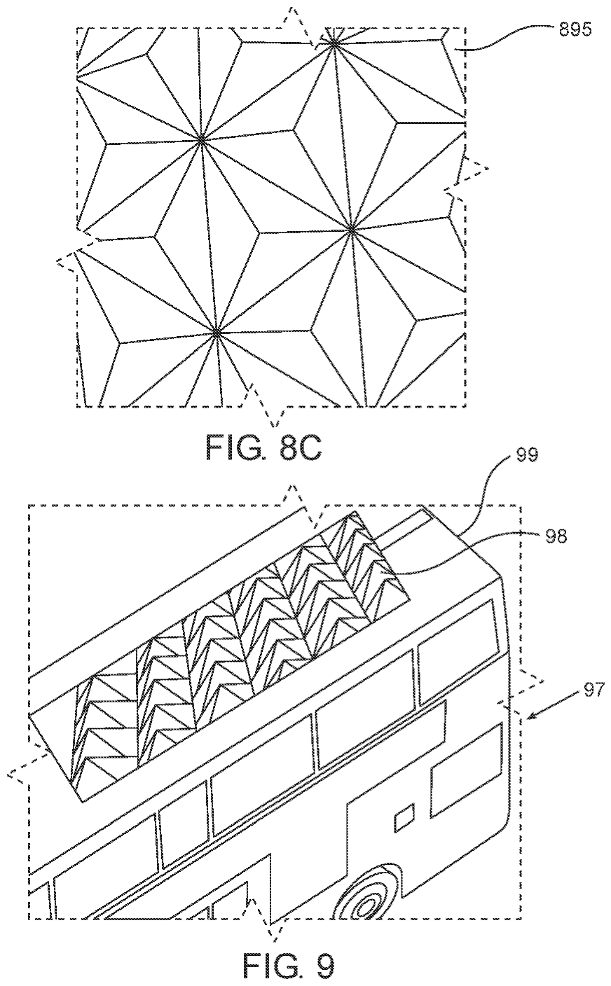

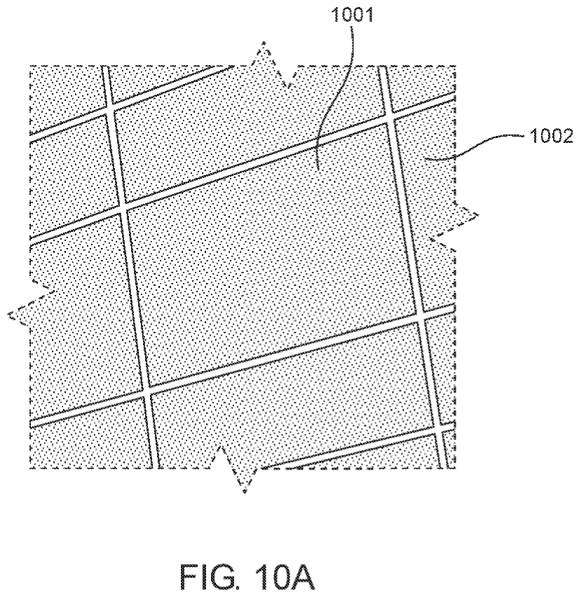

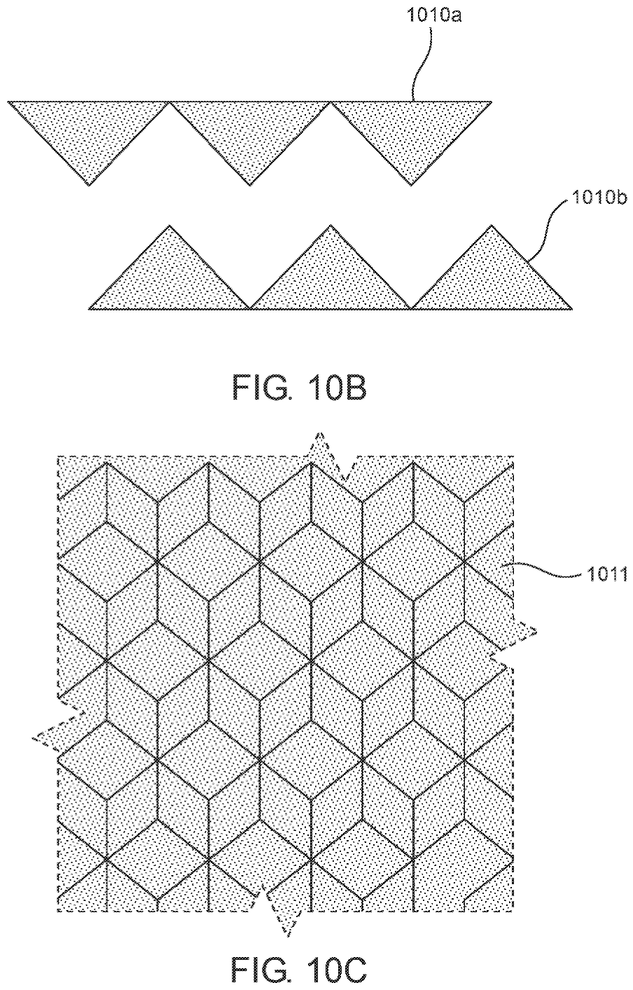

Referring to FIG. 8A schematically illustrating corrugated roofing material, according to the Prior art.

Corrugated transparent and pigmented roofing materials 891 and 892 and with other profiles are known in the art.

Referring to FIG. 8B schematically illustrating solar cells 894 attached to corrugated solar roofing materials 893, in accordance with an embodiment of the disclosed subject matter.

The present disclosure utilizes corrugated, wavy, bulgy, or other surfaces that are used as roofs in logistic warehouses, green houses, posts of public transportation, etc. to act as solar concentrators, instead of placing on the roof a solar system that is relatively expensive and requires heavy installation facilities.

It can be seen that the corrugated structure is provided with different angled surfaces. This can be utilized to be placed on top of the structure itself, or embedding within the structure so that the solar cells are directed to several directions, portion of which are very effective and a portion is less effective, however, still operates at any given time of the day.

In existing light roofs that uses corrugated roofing material 891 or 892 of the art, corrugated solar roofing materials 893 can replace the existing corrugated roofing material, thus retrofitting the roof with energy producing units. Alternatively, corrugated solar roofing materials 893 can be used from the start without having to change the design.

The solar cells can be adhered to the surface of the corrugated structure on the outer side. The solar cells can be adhered to the surface of a transparent structure as seen herein. In case the structure is transparent, the cells can be adhered onto the surface beneath the structure. As can be seen, the cells are oriented in the directions of the corrugated structure so that when the sun is travelling from one side to the other, there is always solar cells that are directed to the sun. The solar cells 894 can cover the entire surface of the corrugated material 893, or only a portion of it, making the structure semi-transparent.

Referring to FIG. 8C schematically illustrating corrugated roofing materials 895, having facets in different orientations, in accordance with an embodiment of the disclosed subject matter.

Roofing materials 895, having facets in different orientations is another example of a structure that can be used in order to adhere the solar cells or embed them in different orientations so as to effectively use the light all day long.

Referring to FIG. 9 schematically illustrating 3D solar panel attached to a vehicle, in accordance with an embodiment of the disclosed subject matter.

In the depicted, non-limited example, a 3D solar panel 98 is attached to the roof 99 of a bus 97. It should be noted that any electric or hybrid vehicle, car or track can be used, and that the 3D solar panel 98 can be of the type disclosed herein.

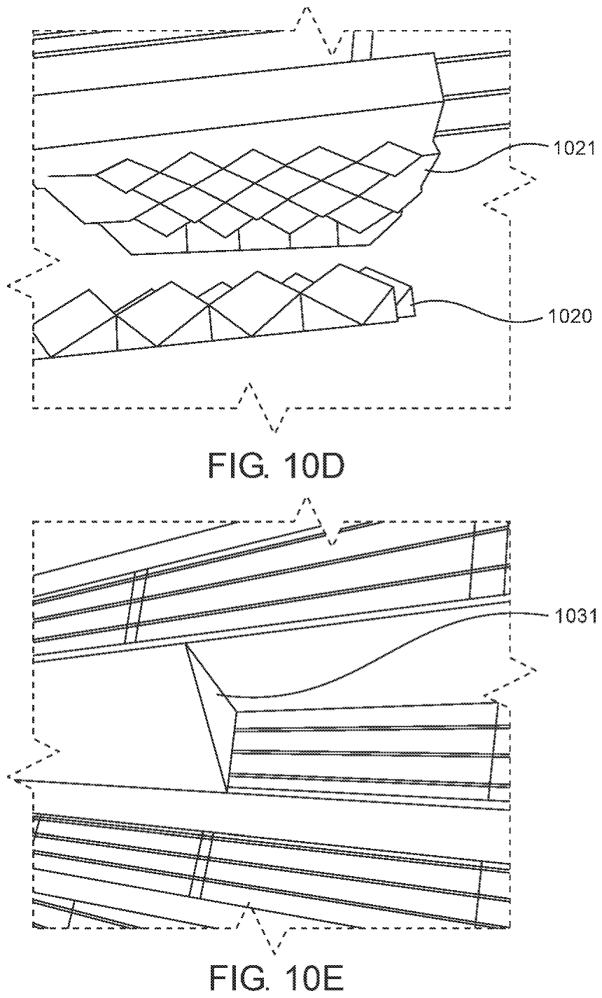

Referring to FIG. 10A schematically illustrating damage caused to solar cells when gluing them to a support structure, or when the cells get hot, according to the prior art.

Since solar cells 1001 are thin and fragile, they often develop cracks 1002 during the process of gluing them to a support structure, and/or the process of applying lamination layer to protect the solar cells, as needed in the exemplary embodiments disclosed herein.

Moreover, such cracks 1002 are caused due to differences in thermal expansion between the solar cell and the plastic carrier structure on which it is applied, or plastic lamination used for protecting the solar cells from the environment. For this reason, embodiments of the current subject matter, uses metal backing for the solar cells.

Referring to FIG. 10B schematically illustrating molds used in adhering solar cells to angulated support structures, in accordance with an embodiment of the disclosed subject matter.

Vacuum forming is often used for laminate solar cells, or to attached them to their support structures. However, it was discovered that when applying vacuum, the lamination layer does not adhere to all the facets of the 3D structures used in embodiments of the current subject matter. Moreover, the concentrated stress caused by this process of the art, often causes cracks in the solar cells, causing reduce efficiency or dysfunction. Soft Silicon, or foam mold, shaped to fit the structure of the 3D surface can be used to solve this problem.

In the depicted embodiment, two such complementary molds 1010a and 1010b, each fit the corresponding side of the 3D structure such as 893, 910, 9530 940 and 950, are used to apply gentle force over the faces of the solar cells and the supporting structures. Two such molds are preferred when the support structure is flexible. One mold can be sufficient when the support structure is rigid.

Referring to FIG. 10C schematically illustrating a 3D mold used in adhering solar cells, in accordance with an embodiment of the disclosed subject matter.

The depicted mold 1011 is used with 3D structures such as structure 900, 895 and the likes.

Referring to FIG. 10D schematically illustrating a 3D mold and a 3D rigid support structure, in accordance with an embodiment of the disclosed subject matter.

When processing a rigid support structure such as transparent 3D structures 952a′ or 1020, a single mold 1021 can be applied only to the side where the solar cells are to be glued.

Referring to FIG. 10E schematically illustrating a soft pressure applying device, in accordance with an embodiment of the disclosed subject matter.

When adhering solar cells to rigid carried such as 521a, 521b, 521c, or 652, pressure applying device 1031b can be used and applied only the side where the solar cells are to be glued.

Although the subject matter has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present subject matter.

1. A prefabricated solar construction element comprising:
a building construction element ready to be integrated into an architectural building;
a plurality of solar cells carriers; and
a plurality of solar cells attached to said plurality of solar cells carriers, wherein the solar cells generate electric power in response to light, wherein the prefabricated solar construction element is prefabricated by integrating the construction element, the plurality of solar cells carriers, and the plurality of solar cells, prior to integrating the prefabricated solar construction element into the architectural building.

2. The prefabricated solar construction element of claim 1, wherein said building construction element comprises:
an inner plate;
an outer plate; and
a thermal isolation layer sandwiched in between said inner plate and said outer plate, and wherein said plurality of solar cells carriers are attached to said outer plate.

3. The prefabricated solar construction element of claim 1, wherein said building construction element comprises:
an inner plate;
an outer plate; and
a thermal isolation layer sandwiched in between said inner plate and said outer plate, and wherein said plurality of solar cells carriers is a part of said outer plate.

4. The prefabricated solar construction element of claim 1, wherein said building construction element includes a transparent plate allowing a portion of the light to pass through the prefabricated solar construction element.

5. The prefabricated solar construction element of claim 4, wherein at least a portion of said transparent plate is in a zig-zag shape having successive surfaces alternating between a zig section at a first angle relative to the plate and zag section at a second angle relative to the plate, and wherein said zig sections are the plurality of solar cells carriers.

6. The prefabricated solar construction element of claim 4, wherein the prefabricated solar construction element is used as a window.

7. The prefabricated solar construction element of claim 4, wherein the prefabricated solar construction element is used as a part of a roof.

8. The prefabricated solar construction element of claim 7, wherein the roof is a roof of a green house.

9. The prefabricated solar construction element of claim 1, wherein said solar cells carriers are made of metal.

10. The prefabricated solar construction element of claim 1, wherein said plurality of solar cells carriers are tilted at a tilting angle respective to the prefabricated solar construction element.

11. The prefabricated solar construction element of claim 10, wherein said tilting angle is selected according to the latitude where said architectural building is to be located.

12. The prefabricated solar construction element of claim 1, wherein the prefabricated solar construction element is an acoustic fence.

13. The prefabricated solar construction element of claim 12, wherein a three-dimensional structure of a face of said acoustic fence has better sound absorbing properties than a flat surface acoustic fence.

14. A dual sided solar unit comprising:
at least a first transparent plate, said first transparent plate is three dimensionally structured, having a first face comprising a plurality of facets oriented in a plurality of angles in respect to said first transparent plate; and
a plurality of solar cells attached to at least some of said plurality of facets, and
wherein the solar cells generate electrical power in response to light falling on any side of the dual sided solar unit.

15. The dual sided solar unit of claim 14, wherein said plurality of solar cells are thin-film solar cells.

16. The dual sided solar unit of claim 14, wherein said plurality of solar cells are dual-sided solar cells, intended to generate electricity in response to light received on any sided of said dual-sided solar cells.

17. The dual sided solar unit of claim 14, wherein each of said plurality of solar cells is a single-sided solar cell, intended to generate electricity in response to light received on an active face of said single-sided solar cell, wherein active faces of said plurality of single-sided solar cells are facing a sun-facing side of said first transparent plate, and wherein at least a portion of the light arriving to the side opposing said sun-facing side of said first transparent plate is reflected or refracted to fall on said active faces of said plurality of single-sided solar cells.

18. The dual sided solar unit of claim 14, further comprising a second transparent plate three dimensionally structured and having a first face comprising a plurality of facets, wherein said plurality of facets are oriented in a plurality of angles in respect to said second transparent plate, wherein a three-dimensional structure of said first face of said second plate match the three-dimensional structure of said first face of said second plate, and wherein said first transparent plate and said second transparent plate are attached together so that said plurality of solar cells are sandwiched in between the first transparent plate and the second transparent plate.

19. The dual sided solar unit of claim 18, wherein the dual sided solar unit operates to generate solar power when positioned vertically.

20. The dual sided solar unit of claim 18, wherein at least one of said first transparent plate or said second transparent plate is a thick, blast resisting plate.
